(19) United States
(12) Patent Application Publication
(10) Pub. No.: US 2026/0186732 A1
(43) Pub. Date: Jul. 2, 2026

(54) INFORMATION PROCESSING APPARATUS, SOUND SYSTEM, SOUND PROCESSING METHOD, AND ONE OR MORE NON-TRANSITORY COMPUTER-READABLE MEDIA

(71) Applicant: Nintendo Co., Ltd., Kyoto-shi (JP)

(72) Inventors: Tatsuya MATSUMOTO, Kyoto-shi (JP); Masato ONISHI, Kyoto-shi (JP); Hironori KAKEMIZU, Kyoto-shi (JP)

(21) Appl. No.: 19/415,145

(22) Filed: Dec. 10, 2025

(30) Foreign Application Priority Data
Dec. 27, 2024 (JP) 2024-232672

(51) Int. Cl. G06F 3/16; G10K 11/178; H03G 3/30; H04M 9/08

(52) U.S. Cl. CPC G06F 3/165; G10K 11/17881; H03G 3/3089; H04M 9/082

(57) ABSTRACT

An information processing apparatus includes a sound system, a microphone sound acquisition unit that acquires a microphone sound, and a second voice chat system that provides a voice chat functionality. The sound system includes a first sound provider configured to provide first sound data corresponding to the microphone sound or second sound data corresponding to silence and a second sound provider configured to provide third sound data corresponding to the microphone sound. While the second voice chat system is running, the sound system causes the first sound provider to provide the second sound data and causes the second sound provider to provide the third sound data.

This non-provisional application is based on Japanese Patent Application No. 2024-232672 filed with the Japan Patent Office on Dec. 27, 2024, the entire contents of which are hereby incorporated by reference.

### FIELD

The present disclosure relates to an information processing apparatus, a sound system, a sound processing method, and one or more non-transitory computer-readable media.

### SUMMARY

(Configuration 1) An exemplary embodiment provides an information processing apparatus configured to execute a game application that implements a first voice chat system. The information processing apparatus includes a sound system, a microphone sound acquisition unit that acquires a microphone sound from a microphone, and a second voice chat system that provides a voice chat functionality. The sound system includes a first sound provider configured to provide first sound data corresponding to the microphone sound or second sound data corresponding to silence to the first voice chat system and a second sound provider configured to provide third sound data corresponding to the microphone sound to the second voice chat system. While the second voice chat system is running, the sound system causes the first sound provider to provide the second sound data and causes the second sound provider to provide the third sound data.

(Configuration 2) In Configuration 1, while the second voice chat system is not running and the first voice chat system is running, the sound system causes the first sound provider to provide the first sound data.

(Configuration 3) In Configuration 1 or 2, the sound system further includes a third sound provider configured to provide fourth sound data corresponding to the microphone sound to the game application. The sound system causes the third sound provider to provide the fourth sound data in response to a request from the game application.

(Configuration 4) In Configuration 3, the sound system further includes an adjuster configured to perform at least one of active noise canceling processing, active echo canceling processing, or automatic gain control processing. The adjuster is configured to adjust the microphone sound input to at least one of the first sound provider, the second sound provider, or the third sound provider.

(Configuration 5) In Configuration 1 or 2, the sound system further includes an adjuster configured to perform at least one of active noise canceling processing, active echo canceling processing, or automatic gain control processing. The adjuster is configured to adjust the microphone sound input to at least one of the first sound provider or the second sound provider.

(Configuration 6) In any of Configurations 1 to 3, the sound system further includes an adjuster configured to perform at least one of active noise canceling processing, active echo canceling processing, or automatic gain control and a fourth sound provider configured to provide fifth sound data to the game application. The fifth sound data corresponds to the microphone sound acquired by the microphone sound acquiring unit and not adjusted by the adjuster. The sound system causes the fourth sound provider to provide the fifth sound data in response to a request from the game application.

(Configuration 7) In any of Configurations 1 to 6, the information processing apparatus further includes the microphone.

(Configuration 8) Another exemplary embodiment provides a sound system implemented on an information processing apparatus configured to execute a game application that implements a first voice chat system. The information processing apparatus includes a microphone sound acquisition unit that acquires a microphone sound from a microphone and a second voice chat system that provides a voice chat functionality. The sound system includes a first sound provider configured to provide first sound data corresponding to the microphone sound or second sound data corresponding to silence to the first voice chat system and a second sound provider configured to provide third sound data corresponding to the microphone sound to the second voice chat system. While the second voice chat system is running, the first sound provider provides the second sound data and the second sound provider provides the third sound data.

(Configuration 9) Another exemplary embodiment provides a sound processing method to be used for an information processing apparatus on which a sound system is implemented, the information processing apparatus being configured to execute a game application that implements a first voice chat system. The information processing apparatus includes a microphone sound acquisition unit that acquires a microphone sound from a microphone and a second voice chat system that provides a voice chat functionality. The sound system includes a first sound provider configured to provide first sound data corresponding to the microphone sound or second sound data corresponding to silence to the first voice chat system and a second sound provider configured to provide third sound data corresponding to the microphone sound to the second voice chat system. The sound processing method includes as processing to be performed by the sound system, while the second voice chat system is running, causing the first sound provider to provide the second sound data and causing the second sound provider to provide the third sound data.

(Configuration 10) Another exemplary embodiment provides a sound processing program to be used for an information processing apparatus on which a sound system is implemented, the information processing apparatus being configured to execute a game application that implements a first voice chat system. The information processing apparatus includes a microphone sound acquisition unit that acquires a microphone sound from a microphone and a second voice chat system that provides a voice chat functionality. The sound system includes a first sound provider configured to provide first sound data corresponding to the microphone sound or second sound data corresponding to silence to the first voice chat system and a second sound provider configured to provide third sound data corresponding to the microphone sound to the second voice chat system. The sound processing program causes the sound system to perform, while the second voice chat system is running, causing the first sound provider to provide the second sound data and causing the second sound provider to provide the third sound data.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 shows an exemplary illustrative non-limiting drawing illustrating a schematic diagram showing an exemplary system according to the present embodiment.

FIG. 2 shows an exemplary illustrative non-limiting drawing illustrating a schematic diagram showing an exemplary hardware configuration of a game terminal according to the present embodiment.

FIG. 3 shows an exemplary illustrative non-limiting drawing illustrating an exemplary sound system in the present embodiment.

FIG. 4 shows an exemplary illustrative non-limiting drawing illustrating exemplary output of sound data when a game chat program is running and a system chat program is not running.

FIG. 5 shows an exemplary illustrative non-limiting drawing illustrating exemplary output of sound data when the game chat program is not running and the system chat program is running.

FIG. 6 shows an exemplary illustrative non-limiting drawing illustrating exemplary output of sound data when both of the game chat program and the system chat program are running.

### DETAILED DESCRIPTION OF NON-LIMITING EXAMPLE EMBODIMENTS

The present embodiment will be described in detail with reference to the drawings. The same or corresponding elements in the drawings have the same reference characters allotted and description thereof will not be repeated.

### Embodiment

### A. Overview

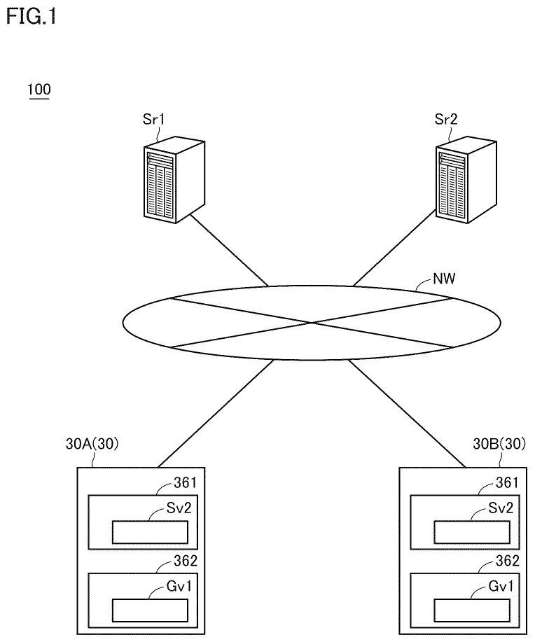

An exemplary configuration of a system 100 according to the present embodiment will be described. Exemplary system 100 according to the present embodiment will be described with reference to FIG. 1. System 100 is, for example, a system that provides a service to a game terminal 30A, 30B, a not-shown another information processing apparatus, or the like by using a server Sr1, Sr2.

System 100 includes server Sr1, Sr2 and game terminal 30A, 30B by way of example. Components included in system 100 are connectable to one another over a network NW. Network NW may be, for example, the Internet.

Each of game terminals 30A and 30B may be, for example, an information processing apparatus exclusive for gaming. Game terminals 30A and 30B will collectively be referred to as a “game terminal 30” below, without being distinguished from each other. Game terminal 30 includes, for example, a system program 361 and a game application 362. System program 361 is a program for causing game terminal 30 to operate, and includes, for example, an OS, firmware, a system chat program Sv2, and the like.

Game application 362 is an application that executes a specific game content. Game application 362 may be stored in game terminal 30, for example, by being downloaded from a not-shown distribution server to game terminal 30 or by insertion of a not-shown cartridge in game terminal 30. A plurality of game applications each of which provides a different game content may be stored in game terminal 30. In other words, game application 362 may be a feature independent of game terminal 30. Game application 362 may newly be added to game terminal 30, or game application 362 stored in game terminal 30 may be erased. In the example in FIG. 1, game application 362 that provides a common game content is stored in game terminals 30A and 30B.

In the present embodiment, system chat program Sv2 is implemented by system program 361. System chat program Sv2 is a program for providing a voice chat functionality to a user who operates game terminal 30. Server Sr1 is a server that performs various types of processing for providing a voice chat service between a plurality of game terminals 30 that execute system chat program Sv2.

In a specific example, server Sr1 receives from game terminal 30A that executes system chat program Sv2, chat information including at least of a voice of a user of game terminal 30A over network NW. The chat information may include, for example, a game execution screen, moving images showing the user, or the like. Server Sr1 transmits the chat information acquired from game terminal 30A to game terminal 30B. Game terminal 30B executes system chat program Sv2 to show the acquired chat information of game terminal 30A to a user of game terminal 30B. The user of game terminal 30B can thus recognize with game terminal 30B, for example, the voice of the user of game terminal 30A.

The chat information including at least the voice of the user of game terminal 30B may be transmitted from game terminal 30B to game terminal 30A. In this case, system 100 may provide a communication service by bidirectional conversations to the users of game terminals 30A and 30B.

System chat program Sv2 may provide the voice chat functionality while it has game terminal 30 execute the game content, or may provide the voice chat functionality to game terminal 30 that is not executing the game content. For example, the voice chat functionality may be provided while the same game application 362 is running in game terminals 30A and 30B, or alternatively, the voice chat functionality may be provided while game applications 362 different between game terminals 30A and 30B are running. The users of game terminals 30A and 30B can thus communicate while they play a game running in their game terminals 30.

In the present embodiment, server Sr2 is a server that provides a service associated with execution of a game content. Server Sr2 may provide a service, for example, of a match game, a cooperative game, or the like. Server Sr2 acquires operation information, for example, from each of game terminals 30A and 30B that executes game application 362 and proceeds with the match game, the cooperative game, or the like in accordance with the operation information.

In the present embodiment, server Sr2 may provide, as a function implemented on game application 362, for example, a service to perform a voice chat while the match game, the cooperative game, or the like is being executed. Game terminal 30 launches the voice chat functionality by executing a game chat program Gv1 implemented within game application 362. Thus, in system 100 in the present embodiment, system chat program Sv2 implemented as the system of game terminal 30 and game chat program Gv1 implemented on game application 362 removable from game terminal 30 are both present.

A scheme to provide the voice chat functionality based on system chat program Sv2 may be referred to as a “system voice chat” below and a scheme to provide the voice chat functionality based on game chat program Gv1 may be referred to as a “game voice chat” below. The game voice chat cannot be launched unless game application 362 is running. The system voice chat may be launchable, on the other hand, when the system of game terminal 30A has been launched, without game application 362 being running. The game voice chat may be launchable when game application 362 is running, even when some kind of game such as the match game, the cooperative game, and the like described above is not being executed. Game terminal 30 in the present embodiment can simultaneously execute system chat program Sv2 and game chat program Gv1.

### B. Exemplary Hardware Configuration

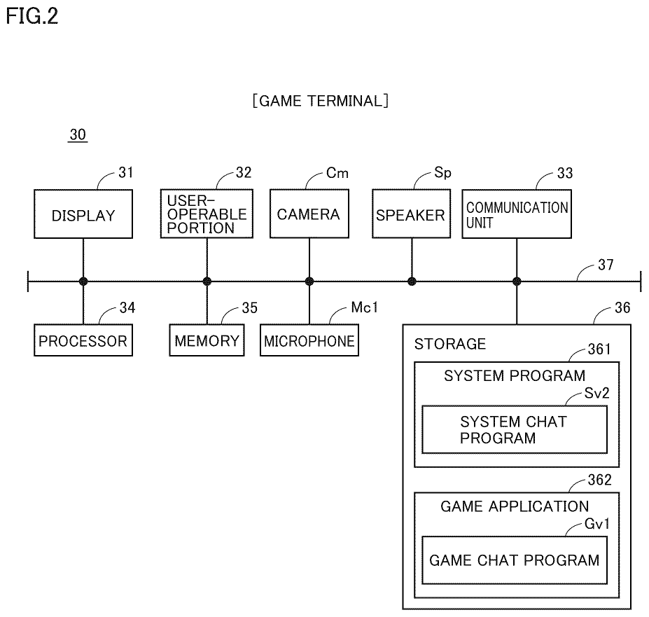

An exemplary hardware configuration of game terminal 30 included in system 100 according to the present embodiment will be described below with reference to FIG. 2.

A schematic diagram showing an exemplary hardware configuration of game terminal 30 according to the present embodiment will be described with reference to FIG. 2. Referring to FIG. 2, game terminal 30 includes, for example, a display 31, a user-operable portion 32, a communication unit 33, one or more processors 34, a memory 35, a storage 36, a camera Cm, a speaker Sp, and a microphone Mc1. These components are connected to communicate data with one another through a bus 37.

Display 31 shows an image generated as a result of information processing performed by processor 34. Display 31 may include a plurality of displays. User-operable portion 32 accepts an operation by a user who operates game terminal 30. User-operable portion 32 may include, for example, a push button, an analog stick, a touch panel, a mouse, a keyboard, or the like.

Communication unit 33 communicates with another information processing terminal included in system 100 over network NW. Communication unit 33 may include at least one of hardware necessary for wired communication and hardware necessary for wireless communication. The entirety or a part of processing by communication unit 33 may be performed by processor 34.

Processor 34 is a processing entity for performing processing provided by game terminal 30. The term “processor” in the present disclosure means, for example, processing circuitry such as a central processing unit (CPU), a micro processing unit (MPU), or a graphics processing unit (GPU). The term “processor” encompasses processing circuitry that performs processing in accordance with instruction codes described in a program, processing circuitry in which a plurality of functions are integrated, such as a system on chip (SoC), hard-wired circuitry, and the like.

Memory 35 is a volatile storage device accessible by processor 34, and for example, a dynamic random access memory (DRAM), a static random access memory (SRAM), or the like may be employed as memory 35. Storage 36 is a non-volatile storage device accessible by processor 34, and for example, a hard disk, a flash memory, or the like may be employed as storage 36. Storage 36 may be, for example, a storage medium attachable to and removable from game terminal, 30 such as an optical disc and a cartridge.

In the present embodiment, system program 361 and game application 362 are stored in storage 36. Processor 34 reads, for example, system program 361 or game application 362 and develops and executes the same on memory 35. The term “memory” herein encompasses at least both of a volatile memory and a non-volatile storage.

Microphone Mc1, camera Cm, and speaker Sp may be used for the voice chat functionality described above. Microphone Mc1 is, for example, a microphone built in game terminal 30, and collects a sound generated therearound, such as utterance of the user. Camera Cm is also similarly a built-in camera, and may pick up an image of the user or the like who plays game terminal 30. Speaker Sp may output music or sound effects as the game is executed, and during the voice chat, it may output a sound or the like indicating contents of utterance of another user.

Various components such as display 31, user-operable portion 32, microphone Mc1, camera Cm, and speaker Sp do not have to be included within game terminal 30. For example, at least one of display 31, user-operable portion 32, microphone Mc1, camera Cm, and speaker Sp may be an external apparatus that is different from game terminal 30 and connectable to game terminal 30 through a wire or wirelessly.

### C. Exemplary Sound System

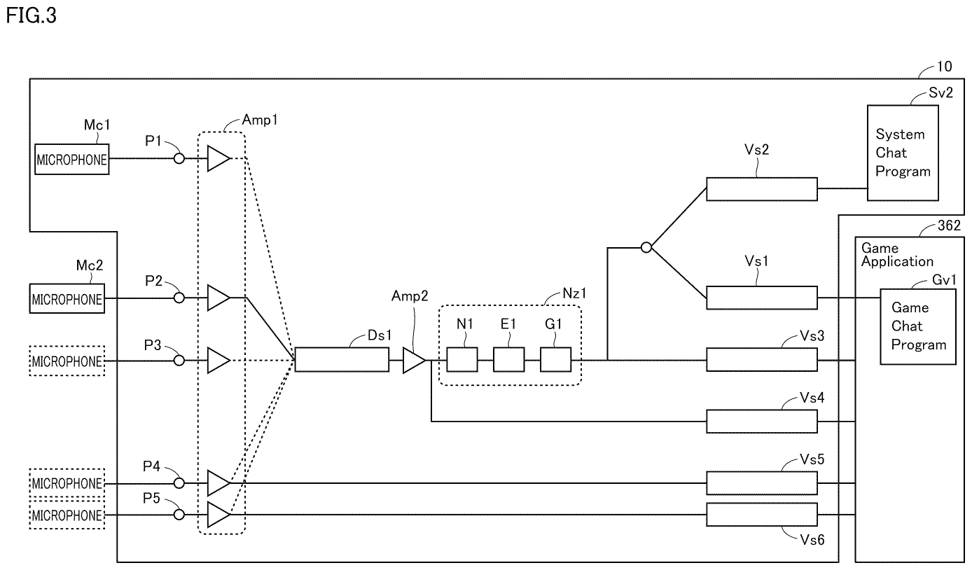

An exemplary sound system 10 in the present embodiment will be described with reference to FIG. 3. FIG. 3 shows a conceptual diagram for illustrating handling of sound data within a single game terminal 30. Sound system 10 is implemented by execution of system program 361 by processor 34, and it is responsible for passing sound data acquired by the microphone to various programs.

Sound system 10 includes microphone Mc1, pins P1 to P5, an amplifier Amp1, a switch Ds1, an amplifier Amp2, an adjuster Nz1, sound providers Vs1 to Vs6, and system chat program Sv2. Each component included in sound system 10 is controlled by processor 34. FIG. 3 shows game application 362 and a microphone Mc2 configured to externally be attached to game terminal 30, as components other than sound system 10. Microphones Mc1 and Mc2 may collectively be referred to as a “microphone Mc” below, without being distinguished from each other, and sound providers Vs1 to Vs6 may collectively be referred to as a “sound provider Vs” below, without being distinguished from one another.

Pins P1 to P5 are sound input and output terminals, each of which accepts audio from the to corresponding microphone Mc. Each of pins P2 to P5 may be, for example, a headphone jack, a universal serial bus (USB) terminal, or the like. FIG. 3 shows an example where microphone Mc2 is connected to pin P2. Pins P2 to P5 may be located at a component other than the components in a main body portion of game terminal 30. For example, in an example where user-operable portion 32 is a controller removable from game terminal 30, pin P2 may be located at the main body portion of game terminal 30 whereas pin P3 may be located at user-operable portion 32.

Each of microphone sounds accepted by pins P1 to P5 is processed as sound data by sound system 10. The sound data input from pins P1 to P5 is amplified by a predetermined amount by amplifier Amp1 to adjust the sensitivity of sound collection by the microphone Mc. The sound data includes both of an analog electrical signal accepted from microphone Mc and a digital signal resulting from conversion by a not-shown A/D converter.

Each of pins P1 to P5 is connected to switch Ds1. Switch Ds1 selects which microphone sound among microphones Mc connected to pins P1 to P5 is output to sound providers Vs1 to Vs4 in accordance with an instruction from processor 34. In the example in FIG. 3, sound data input from pin P2 is controlled to be output to sound providers Vs1 to Vs4. Pins P4 and P5 are connected also to sound providers Vs5 and Vs6, without switch Ds1 being interposed.

Sound data output from switch Ds1 is further amplified by amplifier Amp2 to readjust the sensitivity of microphone Mc. Sound data output from amplifier Amp2 is provided to adjuster Nz1 and to sound provider Vs4.

Adjuster Nz1 includes, for example, at least one of a first adjuster N1, a second adjuster E1, and a third adjuster G1. First adjuster N1 performs active noise canceling processing. The active noise canceling processing is processing for sensing noise included in sound data and reducing noise included in the sound data by outputting a canceling sound reverse in phase to the sensed noise together with the sound data.

Second adjuster E1 performs active echo canceling processing. The active echo canceling processing is processing for canceling an echo by predicting an acoustic echo component that goes around from the speaker to the microphone and subtracting the acoustic echo component from sound data. Third adjuster G1 performs automatic gain control processing. The automatic gain control processing is processing for adjusting a gain to be within an appropriate range with respect to an input signal level by feedback of a peak signal level in sound data. Sound data having noise adjusted by adjuster Nz1 is configured to be output to at least one of sound providers Vs1 to Vs3.

Sound providers Vs1 to Vs6 are functions of sound system 10 to be performed by each of them shown in FIG. 3 to provide corresponding sound data to another program. Sound providers Vs1 to Vs6 are configured such that the function of each of them is performed, for example, by execution of a reusable code included in a library of system program 361. Specifically, a program such as game application 362 can acquire sound data adjusted by adjuster Nz1, by calling sound provider Vs1 by referring to the library of system program 361. Similarly, the program such as game application 362 can acquire sound data not adjusted by adjuster Nz1, by calling sound provider Vs4 by referring to the library of system program 361.

Sound provider Vs2 is prepared to be called by system chat program Sv2. By being called by system chat program Sv2, sound provider Vs2 provides the sound data adjusted by adjuster Nz1 to system chat program Sv2. System chat program Sv2 transmits the sound data acquired at game terminal 30 to which it belongs to another game terminal 30 through server Sr1. System chat program Sv2 can thus provide the system voice chat to the user.

Sound providers Vs1 and Vs3 to Vs6 are prepared to be called by game chat program Gv1. Sound provider Vs1 provides the sound data adjusted by adjuster Nz1 to game chat program Gv1. Game chat program Gv1 transmits the sound data acquired at game terminal 30 to which it belongs to another game terminal 30 through server Sr2. Game chat program Gv1 can thus provide the game voice chat to the user. Thus, in the present embodiment, by way of example, sound providers Vs1 and Vs2 output identical sound data. Thus, in system 100, variation in sound data output between the system voice chat and the game voice chat is suppressed.

Sound provider Vs3 provides the sound data adjusted by adjuster Nz1 to game application 362. Game application 362 can thus proceed with a game, with the use of sound data collected by microphone Mc. In system 100, adjuster Nz1 adjusts noise in the sound data input to each of sound providers Vs1 to Vs3, so that it is not necessary to provide a plurality of noise adjusters for the respective sound providers Vs1 to Vs3. Sound provider Vs4 provides the sound data not adjusted by adjuster Nz1 to game application 362. Game application 362 can thus freely determine which of sound data not adjusted by adjuster Nz1 and sound data adjusted by adjuster Nz1 is to be used. In other words, in system 100, sound data can be provided in accordance with game application 362. For example, in an example where sound data that is a sound other than utterance and desirably not adjusted by adjuster Nz1 is to be used in game application 362, in system 100, sound data not adjusted by adjuster Nz1 can be provided. In other words, game application 362 can select sound data adjusted by adjuster Nz1 or sound data not adjusted by adjuster Nz1, as the sound necessary in proceeding of the game.

Though acquisition of a sound other than utterance via sound provider Vs4 by game application 362 is described in the example above, game application 362 may acquire utterance of the user via sound provider Vs4. For example, game application 362 may perform a function to adjust a sound specific to game application 362. In this case, if game application 362 acquires adjusted sound data via sound provider Vs4, both of game application 362 and sound system 10 perform processing for adjusting sound data in a redundant manner. Game application 362 to which sound system 10 in the present embodiment is applied can select via which of sound provider Vs3 and sound provider Vs4 sound data is to be acquired, even when the sound data is utterance of the user. Thus, in the present embodiment, redundant processing for adjustment of sound data including utterance of the user by both of sound system 10 and game application 362 can be suppressed.

Sound providers Vs5 and Vs6 provide sound data input from respective pins P4 and P5 to game application 362. Game application 362 can thus use, for example, sound data corresponding to sound providers Vs3 to Vs6 in proceeding of the game.

### D. Exemplary Output of Sound Data to Each Chat Program

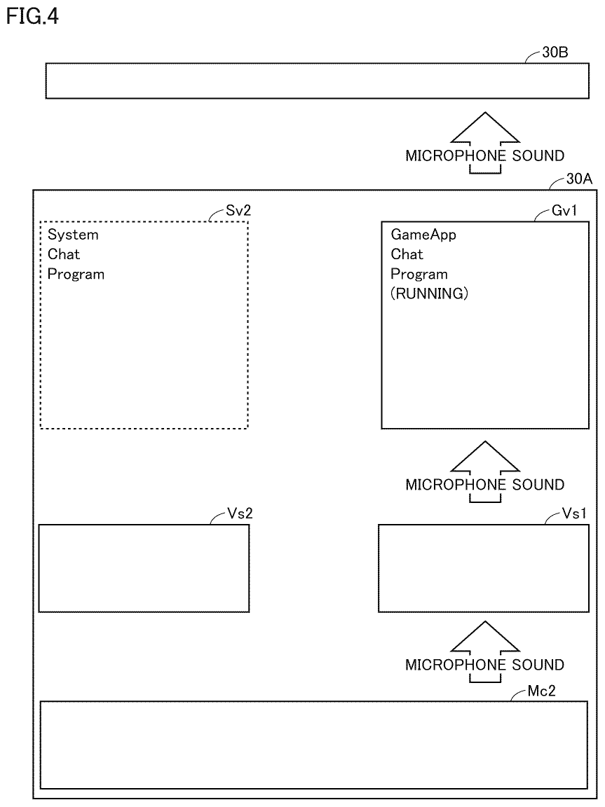

Exemplary input of sound data to each chat program will be described below with reference to FIGS. 4 to 6. FIGS. 4 to 6 show system chat program Sv2 and game chat program Gv1.

Exemplary output of sound data when game chat program Gv1 is running and system chat program Sv2 is not running will be described with reference to FIG. 4. In the example in FIGS. 4 to 6, as in FIG. 3, processor 34 controls switch Ds1 to output sound data corresponding to the microphone sound collected by microphone Mc2 connected to pin P2 to sound providers Vs1 to Vs4. FIG. 4 shows an example where each of game terminal 30A and game terminal 30B executes game chat program Gv1 to perform the game voice chat. In the example in FIG. 4, in game terminal 30A, game chat program Gv1 is running whereas system chat program Sv2 is not running.

Sound data corresponding to the microphone sound input to microphone Mc2 as shown in FIG. 4 is adjusted by adjuster Nz1 and thereafter stored in an area to which sound provider Vs1 can refer. By calling sound provider Vs1, game chat program Gv1 acquires the sound data corresponding to the microphone sound. Game chat program Gv1 transmits the acquired sound data through server Sr2 to game terminal 30B. The user of game terminal 30B who performs the game voice chat can thus hear utterance of the user of game terminal 30A from speaker Sp of game terminal 30B.

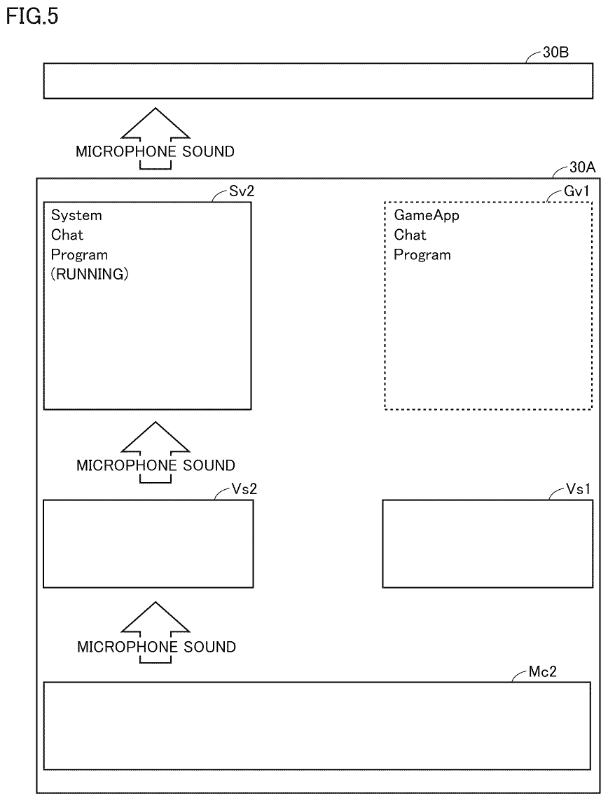

Exemplary output of sound data when game chat program Gv1 is not running and system chat program Sv2 is running will be described with reference to FIG. 5. FIG. 5 shows an example in which each of game terminal 30A and game terminal 30B executes system chat program Sv2 to perform the system voice chat. In the example in FIG. 5, in game terminal 30A, system chat program Sv2 is running whereas game chat program Gv1 is not running.

Sound data corresponding to the microphone sound input to microphone Mc2 is adjusted by adjuster Nz1 and thereafter stored in an area to which sound provider Vs2 can refer. System chat program Sv2 acquires the sound data corresponding to the microphone sound by calling sound provider Vs2. System chat program Sv2 transmits the acquired sound data through server Sr1 to game terminal 30B. The user of game terminal 30B who performs the system voice chat can thus hear utterance of the user of game terminal 30A from speaker Sp of game terminal 30B.

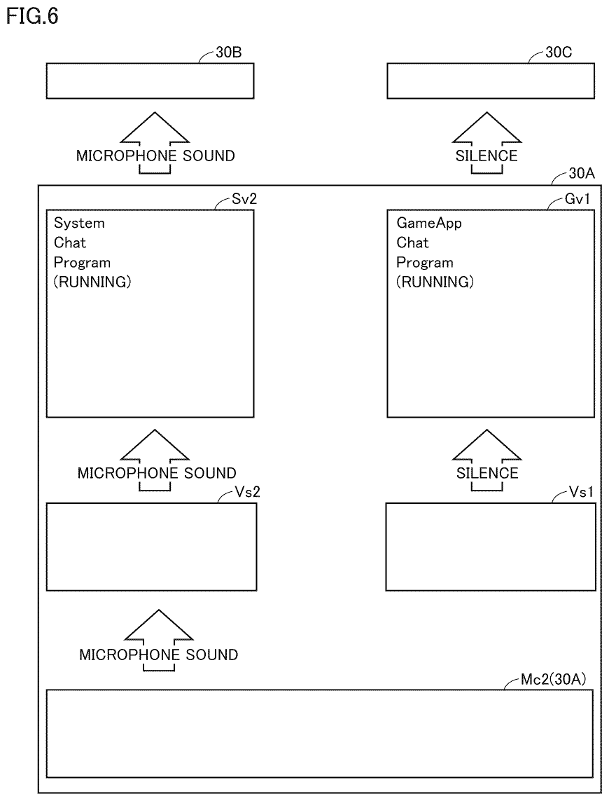

Exemplary output of sound data when both of game chat program Gv1 and system chat program Sv2 are running will be described with reference to FIG. 6. As described above, game terminal 30 in the present embodiment can simultaneously execute system chat program Sv2 and game chat program Gv1. In FIG. 6, each of game terminal 30A and game terminal 30B executes system chat program Sv2 to perform the system voice chat. At the same time, each of game terminal 30A and a game terminal 30C executes game chat program Gv1 to perform the game voice chat.

System 100 in the present embodiment is configured to carry out exclusive control to prioritize system chat program Sv2 over game chat program Gv1 when system chat program Sv2 and game chat program Gv1 are simultaneously running. FIG. 6 shows that the sound data acquired by system chat program Sv2 is transmitted through server Sr1 to game terminal 30B, similarly to FIG. 5.

Since the game voice chat is being performed, game chat program Gv1 calls sound provider Vs1 and requests the sound provider to provide sound data. In the present embodiment, while system chat program Sv2 is running, processor 34 changes the sound data provided by sound provider Vs1 from the microphone sound of microphone Mc2 to sound data indicating silence. Sound provider Vs1 in FIG. 6 thus provides the sound data indicating silence to game chat program Gv1. The sound data indicating silence is not limited to sound data of a waveform having a substantially zero amplitude, and it may be a wavelength out of a general human hearing range. The user of game terminal 30C who performs the game voice chat thus becomes unable to hear utterance of the user of game terminal 30A from speaker Sp.

Thus, in system 100 in the present embodiment, while system chat program Sv2 is running, sound provider Vs2 is caused to provide sound data corresponding to the microphone sound and sound provider Vs1 is caused to provide sound data corresponding to silence. Therefore, when the system voice chat and the game voice chat are simultaneously performed, sound data corresponding to utterance of the user is output only to game terminal 30 which is a counterpart of the system voice chat. System 100 can thus suppress transmission of the sound data corresponding to utterance of the user to both of the counterpart of the system voice chat and a counterpart of the game voice chat and resultant confusion in communication. In addition, game application 362 applied to system 100 does not have to include a program that defines prevention of output of microphone sound data to game chat program Gv1 at the time of launch of system chat program Sv2 while game chat program Gv1 is running. Therefore, system 100 can achieve improvement in efficiency of development of game application 362. Furthermore, in system 100, it is not necessary to provide game terminal 30 with a hardware switch or a software switch for switching between game chat program Gv1 and system chat program Sv2 that should be set as an output destination of the microphone sound, and hence cost can be reduced.

Furthermore, in the present embodiment, sound providers Vs3 to Vs6 are provided as sound provider Vs to be used by game application 362 mainly for the purpose of proceeding of the game, whereas sound provider Vs1 is provided as sound provider Vs to be used by game chat program Gv1. In other words, a developer who develops game chat program Gv1 should only designate sound provider Vs1 from which sound data to be used by game chat program Gv1 should be acquired. System 100 in the present embodiment can thus suppress transmission of sound data to both of the counterpart of the system voice chat and the counterpart of the game voice chat simply by designation of sound provider Vs1 by the developer who develops game chat program Gv1, without programming in consideration of a state of system chat program Sv2.

More specifically, the developer of game chat program Gv1 does not have to perform coding for preventing transmission of sound data to both of the counterpart of the system voice chat and the counterpart of the game voice chat based on launch of system chat program Sv2 while game chat program Gv1 is running. Therefore, in the present embodiment, bugs caused by complication of codes can be suppressed, and furthermore, processing loads when launch and shutdown of system chat program Sv2 is repeated while game chat program Gv1 is running can be reduced. Furthermore, since it is not necessary to implement a program including a logic that defines exclusive relation between the system voice chat and the game voice chat in game application 362, game application 362 that supports the game voice chat can readily be ported and cost can be reduced.

### E. Other Modifications

The example where exclusive control to prioritize system chat program Sv2 over game chat program Gv1 is carried out when system chat program Sv2 and game chat program Gv1 are simultaneously running is described above. In system 100, however, exclusive control to prioritize game chat program Gv1 over system chat program Sv2 may be carried out. Alternatively, processor 34 may control both of system chat program Sv2 and game chat program Gv1 to output silence.

In the example described above, adjuster Nz1 is described as adjusting noise in sound data input to sound providers Vs1 to Vs3. A target of noise adjustment by adjuster Nz1, however, is not limited thereto, and it may be only sound providers Vs1 and Vs2.

In the example described above, adjuster Nz1 is described as performing active noise canceling processing, active echo canceling processing, and automatic gain control processing. Processing performed by adjuster Nz1, however, is not limited thereto, and other noise adjustment processing may be performed, or at least one of them may be performed.

In addition, the example in which each of sound providers Vs1 and Vs2 provides sound data adjusted by adjuster Nz1 is described with reference to FIG. 3. Data provided by each of sound providers Vs1 and Vs2, however, does not have to be identical sound data. For example, sound provider Vs1 may perform some processing on sound data provided thereby for application to the game voice chat. Similarly, for example, sound provider Vs2 may perform some processing on sound data provided thereby for application to the system voice chat.

In the present embodiment, on condition that system chat program Sv2 is set to a running state, processor 34 changes sound data provided by sound provider Vs1 to sound data indicating silence. The condition for change of the sound data provided by sound provider Vs1 to the sound data indicating silence, however, is not limited to the condition that system chat program Sv2 is set to the running state. For example, the condition may be that both of system chat program Sv2 and game chat program Gv1 are set to the running state.

Although the present invention has been described and illustrated in detail, it is clearly understood that the same is by way of illustration and example only and is not to be taken by way of limitation, the scope of the present invention being interpreted by the terms of the appended claims.

What is claimed is:

1. An information processing apparatus configured to execute a game application including a first voice chat system, the information processing apparatus comprising:
one or more processors; and
one or more memories storing instructions that, when executed by the one or more processors, cause the information processing apparatus to implement
a sound system,
an acquisition module configured to acquire a microphone sound from a microphone, and
a second voice chat system configured to provide a voice chat functionality, wherein
the sound system comprises
a first sound provider configured to provide first sound data corresponding to the microphone sound or second sound data corresponding to silence to the first voice chat system, and
a second sound provider configured to provide third sound data corresponding to the microphone sound to the second voice chat system, and
while the second voice chat system is running, the sound system
causes the first sound provider to provide the second sound data, and
causes the second sound provider to provide the third sound data.

2. The information processing apparatus according to claim 1, wherein
while the second voice chat system is not running and the first voice chat system is running, the sound system causes the first sound provider to provide the first sound data.

3. The information processing apparatus according to claim 1, wherein
the sound system further comprises a third sound provider configured to provide fourth sound data corresponding to the microphone sound to the game application, and
the sound system causes the third sound provider to provide the fourth sound data in response to a request from the game application.

4. The information processing apparatus according to claim 3, wherein
the sound system further comprises an adjuster configured to perform at least one of active noise canceling processing, active echo canceling processing, or automatic gain control processing, and
the adjuster is configured to adjust the microphone sound input to at least one of the first sound provider, the second sound provider, or the third sound provider.

5. The information processing apparatus according to claim 1, wherein
the sound system further comprises an adjuster configured to perform at least one of active noise canceling processing, active echo canceling processing, or automatic gain control processing, and
the adjuster is configured to adjust the microphone sound input to at least one of the first sound provider or the second sound provider.

6. The information processing apparatus according to claim 1, wherein
the sound system further comprises
an adjuster configured to perform at least one of active noise canceling processing, active echo canceling processing, or automatic gain control, and
a fourth sound provider configured to provide fifth sound data to the game application,
the fifth sound data corresponds to the microphone sound acquired by the acquisition module and not adjusted by the adjuster, and
the sound system causes the fourth sound provider to provide the fifth sound data in response to a request from the game application.

7. The information processing apparatus according to claim 1, further comprising the microphone.

8. A sound system implemented on an information processing apparatus configured to execute a game application that implements a first voice chat system, the information processing apparatus comprising an acquisition module configured to acquire a microphone sound from a microphone and a second voice chat system configured to provide a voice chat functionality, the sound system comprising:
a first sound provider configured to provide first sound data corresponding to the microphone sound or second sound data corresponding to silence to the first voice chat system; and
a second sound provider configured to provide third sound data corresponding to the microphone sound to the second voice chat system, wherein
while the second voice chat system is running,
the first sound provider provides the second sound data, and
the second sound provider provides the third sound data.

9. A method for an information processing apparatus configured to execute a game application including a first voice chat system, the information processing apparatus comprising an acquisition module configured to acquire a microphone sound from a microphone and a second voice chat system configured to provide a voice chat functionality, a sound system comprising a first sound provider configured to provide first sound data corresponding to the microphone sound or second sound data corresponding to silence to the first voice chat system and a second sound provider configured to provide third sound data corresponding to the microphone sound to the second voice chat system, the method comprising:
while the second voice chat system is running, causing the first sound provider to provide the second sound data and causing the second sound provider to provide the third sound data.

10. One or more non-transitory computer-readable media implemented on an information processing apparatus configured to execute a game application that implements a first voice chat system, the information processing apparatus comprising an acquisition module configured to acquire a microphone sound from a microphone and a second voice chat system configured to provide a voice chat functionality, a sound system comprising a first sound provider configured to provide first sound data corresponding to the microphone sound or second sound data corresponding to silence to the first voice chat system and a second sound provider configured to provide third sound data corresponding to the microphone sound to the second voice chat system, the one or more non-transitory computer-readable media storing executable instructions that, when executed, cause one or more processing circuits to perform operations comprising:
while the second voice chat system is running, causing the first sound provider to provide the second sound data and causing the second sound provider to provide the third sound data.
